(19) United States
(12) Patent Application Publication
(10) Pub. No.: US 2026/0307191 A1
(43) Pub. Date: Oct. 8, 2026

(54) SUBSTRATE HOLDING APPARATUS AND SUBSTRATE BONDING APPARATUS

(71) Applicant: SCREEN Holdings Co., Ltd., Kyoto (JP)

(72) Inventors: Hidehiro MAEDA, Tokyo (JP); Takashi SHIOMI, Tokyo (JP)

(21) Appl. No.: 19/637,835

(22) Filed: Apr. 2, 2026

(30) Foreign Application Priority Data
Apr. 4, 2025 (JP) 2025-062532

(51) Int. Cl. B23Q 3/16; B23Q 3/18

(52) U.S. Cl. CPC B23Q 3/16; B23Q 3/186

(57) ABSTRACT

There is provided a substrate holding apparatus including a holding plate that holds a substrate on a holding surface, actuators that are coupled to the holding plate and deform the holding plate at least in a normal direction of the holding surface, a base plate that supports the actuators, a table main body that supports the base plate, and a mechanism that is disposed between the table main body and the base plate and is deformed according to a reaction force of the actuators generated in the base plate. There may be further provided a substrate bonding apparatus including the substrate holding apparatus, and a substrate holding portion that holds another substrate, wherein the substrate and the other substrate are bonded to each other by at least one of the substrate holding apparatus and the substrate holding portion moving such as to approach the other.

### CROSS REFERENCE TO RELATED APPLICATIONS

This application claims priority to Japanese Patent Application No. 2025-062532 filed on Apr. 4, 2025 in the Japan Patent Office, the entire content of which is incorporated herein by reference.

### BACKGROUND OF THE INVENTION

### 1. Field of the Invention

The present invention relates to a substrate holding apparatus and a substrate bonding apparatus.

### 2. Description of the Related Art

Japanese Patent Application Publication No. 2013-8804 describes that “when a pair of substrates 121 to be bonded are positioned in a positioning portion 170, alignment marks 128 of the substrates 121 facing each other are observed by microscopes 231 and 251 to measure a relative position between the substrates 121. Furthermore, the substrate 121 can be aligned by moving a fine moving stage 230 to eliminate the deviation of the measured relative position.” (paragraph 0055).

### SUMMARY OF THE INVENTION

In a first aspect, there is provided a substrate holding apparatus including a holding plate that holds a substrate on a holding surface, a plurality of actuators that are coupled to the holding plate and deform the holding plate at least in a normal direction of the holding surface, a base plate that supports the plurality of actuators, a table main body that supports the base plate, and a mechanism that is disposed between the table main body and the base plate and is deformed according to a reaction force of the plurality of actuators generated in the base plate.

In the substrate holding apparatus, the mechanism may have a fixing supporting portion that fixes and supports the base plate and the table main body, and a damper disposed between the base plate and the table main body. The fixing supporting portion may be disposed in a region overlapping a center of the base plate, and a plurality of the dampers may be disposed in a region overlapping an edge of the base plate.

In the substrate holding apparatus, the mechanism may have a hinge that prevents deformation of the table main body against deformation of the base plate. The hinge may be deformed according to at least one of inclination and radial movement of the base plate.

The substrate holding apparatus may further include a plate spring that couples the base plate and the holding plate.

In the substrate holding apparatus, each of the plurality of actuators may have a link mechanism that is movable in a planar direction with respect to the holding plate and transmits displacement of the actuator in the normal direction.

The substrate holding apparatus may further include an index that is disposed on the table main body and detects a position of the table main body.

In a second aspect, a substrate bonding apparatus is provided. The substrate bonding apparatus includes a substrate holding portion that holds another substrate. In any one of the substrate bonding apparatuses, the substrate and the other substrate are bonded to each other by at least one of the substrate holding apparatus and the substrate holding portion moving such as to approach the other.

In any one of the substrate bonding apparatuses, the substrate holding apparatus may be movable in the planar direction of the substrate.

The summary of the invention does not recite all of the features of the present invention. A subcombination of these feature groups can also be an invention.

The above and yet other objects, features, and effects of the present invention will become more apparent from the following description of the preferred embodiments made with reference to the attached drawings.

### BRIEF DESCRIPTION OF THE DRAWINGS

FIG. 1 is a schematic plan view of a stacked body manufacturing system 100.

FIG. 2 is a schematic longitudinal sectional view of a substrate bonding apparatus 170.

FIG. 3 is a schematic sectional view of the substrate bonding apparatus 170.

FIG. 4 illustrates an example of how the stacked body manufacturing system 100 bonds substrates 121 together.

FIG. 5 is a conceptual perspective view of a pair of the substrates 121 to be bonded while facing each other.

FIG. 6 is a schematic plan view of a holding portion 220 and a fine moving stage 230.

FIG. 7 is a schematic A-A sectional view of the holding portion 220 and the fine moving stage 230.

FIG. 8 is a schematic B-B sectional view of the holding portion 220.

FIG. 9 is a schematic C-C sectional view of the holding portion 220.

FIG. 10 is a schematic enlarged view of a portion indicated by a broken line in FIG. 9.

FIG. 11 is a schematic C-C sectional view of the holding portion 220.

FIG. 12 schematically illustrates a hinge 650 used as a supporting portion.

FIG. 13 schematically illustrates a fixing supporting portion 670 and a damper 672 which are used as supporting portions.

### DETAILED DESCRIPTION OF THE PREFERRED EMBODIMENTS

The following preferred embodiments do not limit the invention according to the claims. Not all combinations of features described in the preferred embodiments are essential to the solution of the invention.

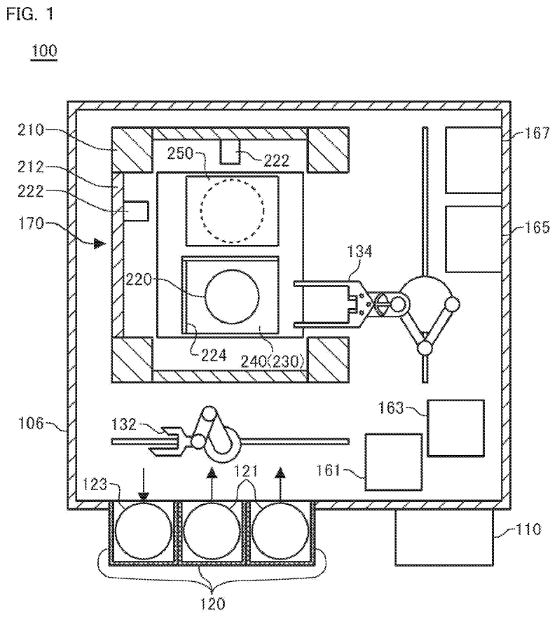

FIG. 1 s an arrangement view illustrating a stacked body manufacturing system 100 according to the present preferred embodiment. The stacked body manufacturing system 100 includes a housing 106, a substrate case 120, a first transfer robot 132, a substrate buffer 161, a substrate position adjustment portion 163, a second transfer robot 134, an activation apparatus 165, a cleaning apparatus 167, a substrate bonding apparatus 170, and a controller 110. The stacked body manufacturing system 100 manufactures a stacked body 123 formed by stacking a plurality of substrates 121. A substrate 121 is, for example, a circular silicon substrate on which a circuit pattern, an alignment mark, an electrode, etc., is formed. The stacked body manufacturing system 100 can also stack unprocessed substrates, compound semiconductor substrates, printed substrates, glass substrates, etc. A substrate on which a circuit pattern, etc., is formed and an unprocessed substrate can also be stacked, and the same type of substrates such as substrates on which a circuit pattern is formed or unprocessed substrates can also be stacked. The substrate 121 to be stacked itself may be a substrate already formed by stacking a plurality of substrates. The substrate 121 to be stacked is not limited to a circular substrate, and may be a square-shaped substrate.

The substrate case 120 is a case capable of accommodating the substrate 121, and accommodates the substrate 121 on which a circuit pattern, etc., is formed. The first transfer robot 132 takes out the substrate 121 from the substrate case 120 and transfers the substrate 121 to the substrate buffer 161 or the substrate position adjustment portion 163. The substrate buffer 161 temporarily stocks the substrate 121. The substrate position adjustment portion 163 pre-aligns the substrate 121 before the substrate 121 is transferred to various apparatuses such as the activation apparatus 165, the cleaning apparatus 167, and the substrate bonding apparatus 170. The second transfer robot 134 transfers the substrate 121 between the substrate buffer 161, the substrate position adjustment portion 163, the activation apparatus 165, the cleaning apparatus 167, and the substrate bonding apparatus 170.

The activation apparatus 165 activates a front surface of the substrate 121. Specifically, the front surface of the substrate 121 is activated by plasma processing. The cleaning apparatus 167 cleans the substrate 121 activated by the activation apparatus 165. The substrate 121 cleaned by the cleaning apparatus 167 is transferred to the substrate bonding apparatus 170. The substrate bonding apparatus 170 stacks (bonds) the two substrates 121.

The controller 110 includes an arithmetic processing circuit such as a CPU and a memory such as a ROM and a RAM, and executes a predetermined program to realize a function thereof. The controller 110 is, for example, a computer, and integrally controls each portion of the stacked body manufacturing system 100. The controller 110 controls driving of the first transfer robot 132, the second transfer robot 134, the substrate position adjustment portion 163, the activation apparatus 165, the cleaning apparatus 167, and the substrate bonding apparatus 170.

The stacked body manufacturing system 100 includes the substrate bonding apparatus 170 disposed in the housing 106. The stacked body manufacturing system 100 manufactures the stacked body 123 by bonding the plurality of substrates 121.

The stacked body 123 manufactured in the stacked body manufacturing system 100 is accommodated in another substrate case 120 and carried out from the stacked body manufacturing system 100. By thus using the substrate case 120, the plurality of substrates 121 can be collectively loaded into the stacked body manufacturing system 100, and the plurality of stacked bodies 123 can be collectively carried out from the stacked body manufacturing system 100.

The first transfer robot 132 disposed facing the substrate case 120 carries out the substrate 121 to be bonded from the substrate case 120. In addition, the first transfer robot 132 carries the manufactured stacked body 123 into the substrate case 120. The first transfer robot 132 thus directly transfers the substrate 121 or the stacked body 123.

The substrate bonding apparatus 170 includes a fixed stage portion 250 and a moving stage portion 240 disposed inside a frame body 210. The fixed stage portion 250 is fixed to the frame body 210. The moving stage portion 240 includes a fine moving stage 230 that moves relative to the fixed stage portion 250. A holding portion 220 is disposed on the fine moving stage 230. The moving stage portion 240 moves relative to the fixed stage portion 250 in a state where the holding portion 220 grips the substrate 121.

An outer surface of the frame body 210 is closed by a wall member 212, and the influence of the radiation heat from the surroundings on the substrate bonding apparatus 170 is eliminated. The fine moving stage 230 includes a reflecting mirror 224. An interferometer 222 is disposed inside the wall member 212. The interferometer 222 uses the reflecting mirror 224 to measure the position of the fine moving stage 230 with high accuracy. As a result, the substrate 121 held by the holding portion 220 can be positioned with high accuracy with respect to the substrate 121 held by a holding portion 252 of the fixed stage portion 250. In other words, it can also be said that the reflecting mirror 224 is an index for detecting the position of the fine moving stage 230.

After the positioning, the fine moving stage 230 moves toward the fixed stage portion 250, and the stacked body manufacturing system 100 bonds the substrates 121 to each other and forms the stacked body 123. The stacked body 123 is delivered to the second transfer robot 134 and the first transfer robot 132 and collected in the substrate case 120.

In addition, the controller 110 includes an operation portion operated by a user from the outside in a case where the power of the stacked body manufacturing system 100 is turned on and various settings, information, etc., are input, a display portion that transmits information to the user, etc. Furthermore, the controller 110 may include a connection portion connected to another device additionally placed.

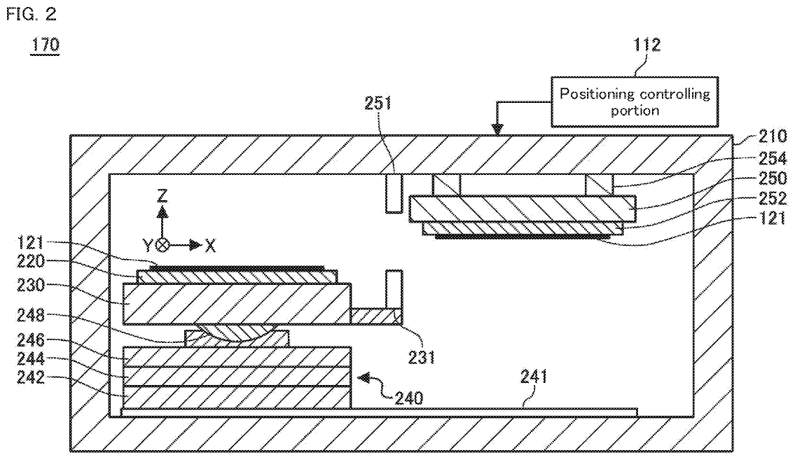

FIG. 2 is a schematic longitudinal sectional view of the substrate bonding apparatus 170. The fixed stage portion 250 is suspended downward from a ceiling surface of the frame body 210 through a plurality of load cells 254. The fixed stage portion 250 includes the holding portion 252. The holding portion 252 may be a vacuum chuck. The holding portion 252 holds the substrate 121 vertically downward. The load cell 254 detects a vertically downward force acting on the fixed stage portion 250.

On the ceiling surface of the frame body 210, a vertically downward microscope 251 is disposed at the side of the fixed stage portion 250. The microscope 251 observes the front surface of the substrate 121 held by the holding portion 220. Since the microscope 251 is fixed to the frame body 210, the relative position between the microscope 251 and the fixed stage portion 250 does not change.

The moving stage portion 240 includes a moving surface plate 242, a rough moving stage 244, a gravity canceling portion 246, a spherical seat 248, and the fine moving stage 230. The moving surface plate 242 is mounted with the rough moving stage 244, the gravity canceling portion 246, and the fine moving stage 230, and moves along a guide rail 241 fixed to an inner bottom surface of the frame body 210. By the movement of the moving surface plate 242, the moving stage portion 240 moves between a position immediately below the fixed stage portion 250 and a position deviated from the position immediately below the fixed stage portion 250.

The rough moving stage 244 moves, with respect to the moving surface plate 242, in a horizontal direction including an X direction component and a Y direction component indicated by arrows in the drawing. When the rough moving stage 244 moves relative to the moving surface plate 242, the fine moving stage 230 also moves along with the rough moving stage 244.

The gravity canceling portion 246 expands and contracts while detecting fine displacement of the fine moving stage 230 and reduces the apparent weight of the fine moving stage 230. As a result, the load of an actuator that displaces the fine moving stage 230 is reduced, and the control accuracy of the position is improved.

The holding portion 220 is disposed on the fine moving stage 230. The holding portion 220 holds the substrate 121 to be bonded. In the positioning operation of the substrate 121, the fine moving stage 230 moves along with the movement of the moving surface plate 242 and the rough moving stage 244 provided on the moving surface plate 242. In the next stage, the fine moving stage 230 is displaced with respect to the rough moving stage 244. The displacement of the fine moving stage 230 with respect to the rough moving stage 244 includes translation and rotation with respect to all of the X, Y, and Z axes. The displacement amount of the fine moving stage 230 is sufficiently small, and even if the fine moving stage 230 is displaced, it does not come into contact with a push-up pin 623 to be described later. In other words, with the above arrangement, the moving stage portion 240 is movable at least in a planar direction of the substrate 121. A positioning controlling portion 112 controls the displacement of the moving surface plate 242, the rough moving stage 244, and the fine moving stage 230.

In addition, the fine moving stage 230 includes a microscope 231 fixed at the side. Since the microscope 231 is fixed to the fine moving stage 230, the relative position between the fine moving stage 230 and the microscope 231 does not change. The microscope 231 observes the front surface of the substrate 121 held by the fixed stage portion 250. The substrate bonding apparatus 170 measures the relative position between the substrates 121 using the observation results of the microscope 231 and the microscope 251.

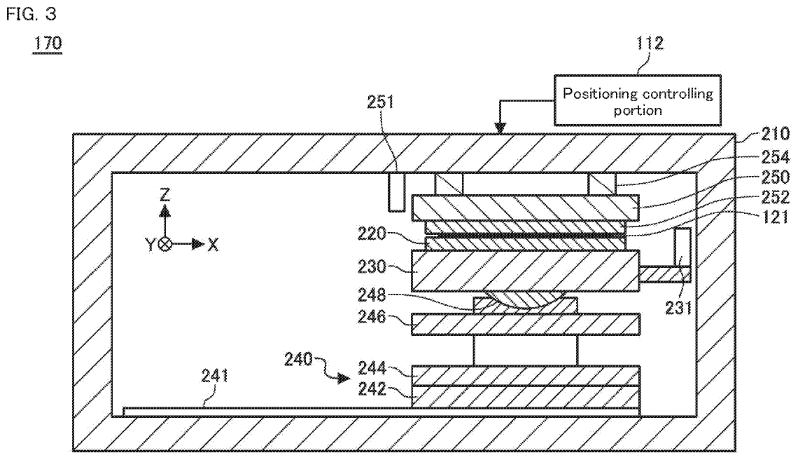

FIG. 3 is a schematic sectional view of the substrate bonding apparatus 170. Elements common to those in FIG. 2 are denoted by the same reference numerals, and redundant description is omitted.

The moving surface plate 242 and the holding portion 220 provided above the moving surface plate 242 move along the guide rail 241.

The moving surface plate 242 moves along the guide rail 241 and causes the substrate 121 gripped by the holding portion 252 and the substrate 121 gripped by the holding portion 220 to face each other. After a pair of the held substrates 121 are positioned, the fine moving stage 230 is raised, and the pair of substrates 121 approach each other.

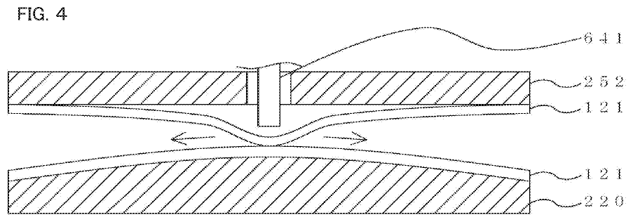

FIG. 4 illustrates an example of how the stacked body manufacturing system 100 bonds substrates 121 together. In the example illustrated in FIG. 4, the holding portion 220 and the substrate 121 held by the holding portion 220 are entirely deformed into a shape in which a center thereof is further raised than a periphery thereof. The holding portion 252 includes a pressing projection 641 at the center thereof. The pressing projection 641 is displaced in a vertical direction. First, the pressing projection 641 is displaced vertically downward from the center of the holding portion 252, and presses a central portion of the substrate 121 gripped by the holding portion 252. Thereafter, the substrate 121 held by the holding portion 220 approaches the substrate 121 gripped by the holding portion 252.

Since the front surfaces of the substrates 121 are activated, when the central portions come into contact with each other, adjacent regions are autonomously adsorbed and bonded to each other by the intermolecular force between the substrates 121. After the substrates 121 are partially brought into contact with each other, the holding portion 252 releases the holding of the substrate 121. A region where the substrates 121 are bonded to each other sequentially expands from a contact portion to the adjacent region. As a result, a bonding wave in which the contact region sequentially expands is generated, and bonding between the substrates 121 progresses. The bonding wave progresses in a direction of an arrow from the center toward an end portion of the substrate 121. Eventually, the substrates 121 come into contact with each other over an entire surface and are bonded to each other. As a result, the substrates 121 form the stacked body 123.

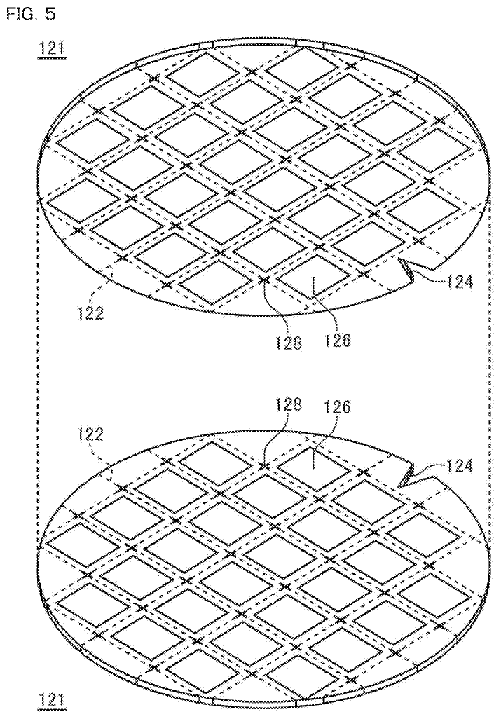

FIG. 5 is a conceptual perspective view of the pair of substrates 121 to be bonded while facing each other. A broken line connecting both ends of the two substrates 121 indicates that the two substrates 121 face each other to be bonded. The substrate 121 has a disk shape partially notched by a notch 124, and has a plurality of element regions 126 and a plurality of alignment marks 128 on the front surface.

The notch 124 is formed corresponding to the crystal orientation, etc., of the substrate 121. Therefore, when the substrate 121 is handled, the direction of the substrate 121 can be determined using the notch 124 as an index.

The plurality of element regions 126 are disposed on the front surface of the substrate 121. In each of the element regions 126, a semiconductor device formed by processing the substrate 121 by a photolithography technique, etc., is mounted. In addition, each of the element regions 126 also includes a pad, etc., serving as a connection terminal when the substrate 121 is bonded to another substrate 121.

There is a blank region where no functional element such as an element or a circuit is disposed between the plurality of element regions 126. In the blank region, a scribe line 122 for cutting when the substrate 121 is cut for each element region 126 is disposed.

Further, the alignment mark 128 serving as an index for positioning the substrate 121 is disposed on the scribe line 122. Since the scribe line 122 disappears as a sawtooth margin in the process of cutting the substrate 121 into dies, providing the alignment mark 128 does not reduce the effective area of the substrate 121.

Although the element region 126 and the alignment mark 128 are drawn large in the drawing, for example, the number of element regions 126 formed on the substrate 121 having a diameter of 300 mm may be several hundred or more. In addition, a wiring pattern, etc., formed in the element region 126 may be used as the alignment mark 128.

When the pair of substrates 121 to be bonded are positioned in the substrate bonding apparatus 170, the alignment marks 128 of the substrates 121 facing each other are observed by the microscopes 231 and 251, and the substrate bonding apparatus 170 measures the relative position between the substrates 121. Furthermore, the substrate bonding apparatus 170 adjusts the position of each of the substrates 121 by moving the fine moving stage 230 to eliminate the deviation of the measured relative position.

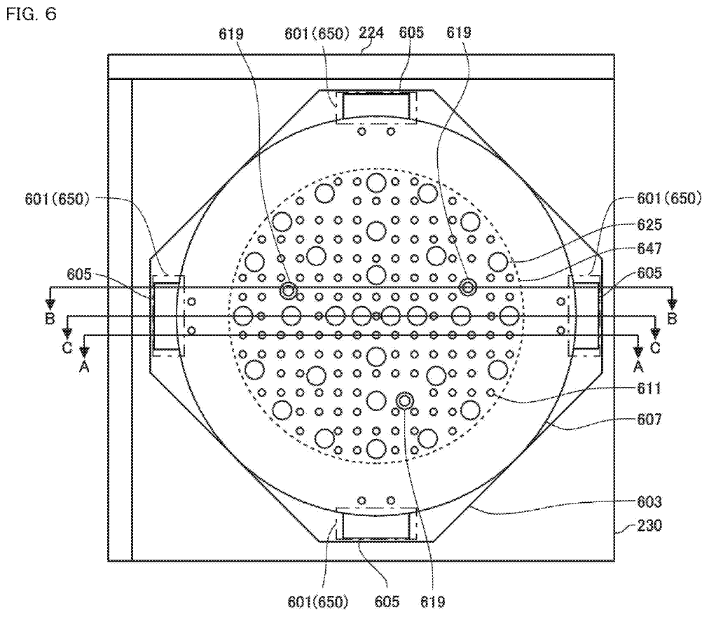

FIGS. 6 to 9 illustrate the holding portion 220 and the fine moving stage 230. In FIGS. 6 to 12, illustration of the substrate 121 is omitted for simplicity.

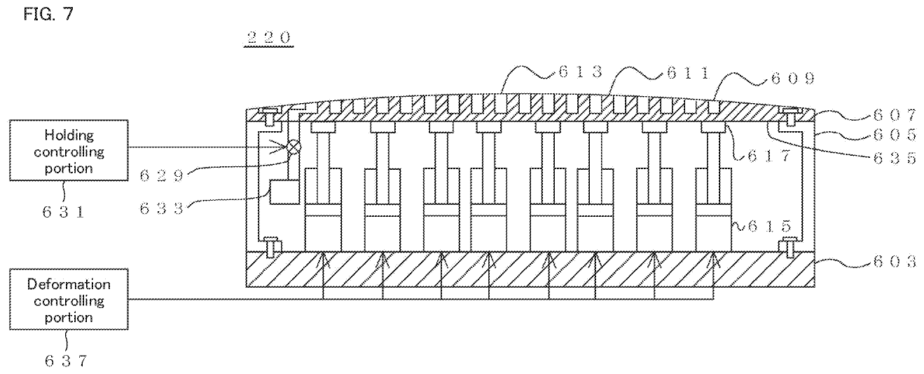

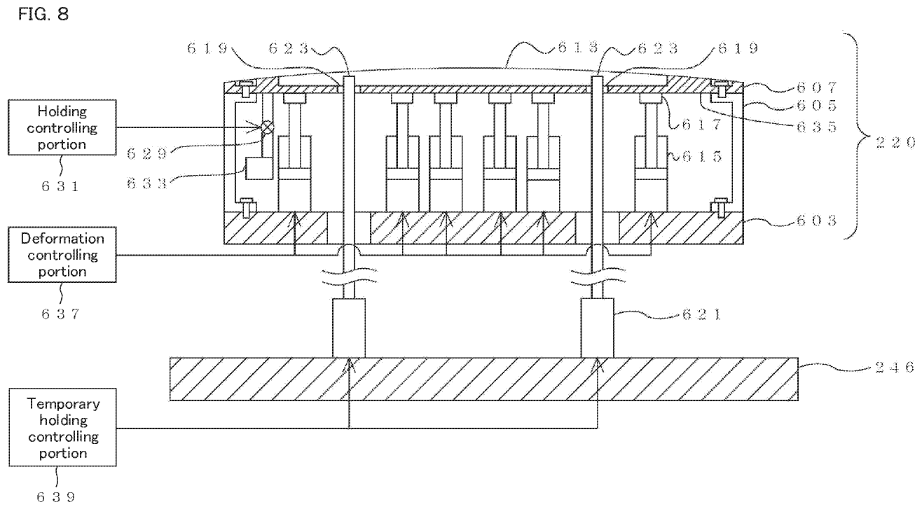

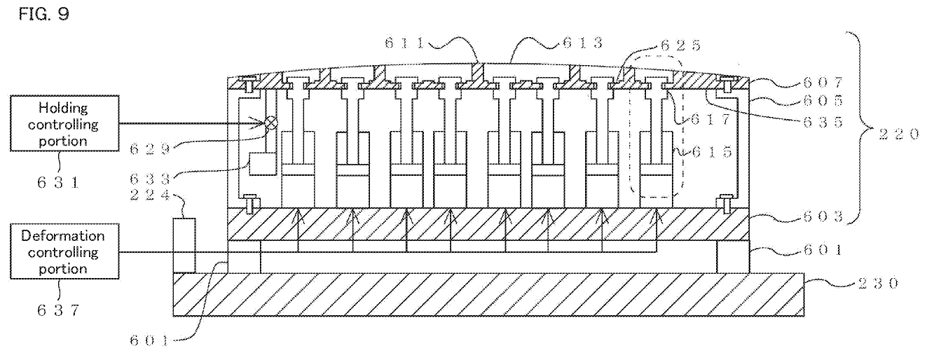

FIG. 6 is a schematic plan view of the holding portion 220 and the fine moving stage 230. A circle 647 indicated by a broken line in FIG. 6 indicates an outer diameter of the substrate 121 when the substrate 121 is held. FIG. 7 is a schematic A-A sectional view of the holding portion 220 and the fine moving stage 230 taken along line A-A of FIG. 6. FIG. 8 is a schematic B-B sectional view of the holding portion 220 taken along line B-B of FIG. 6. FIG. 9 is a schematic C-C sectional view of the holding portion 220 taken along line C-C of FIG. 6.

FIGS. 6 to 9 illustrate the holding portion 220 in a state where an actuator 615 is not operated. The reflecting mirror 224 and the fine moving stage 230 are omitted in FIGS. 7 and 8.

The fine moving stage 230 includes the reflecting mirror 224 and a supporting portion 601. The holding portion 220 includes a base plate 603, a plate spring 605, a holding plate 607, the actuator 615, a valve 629, a negative pressure source 633, a holding controlling portion 631, and a deformation controlling portion 637. The holding plate 607 includes a suction portion 609, a supporting projection 611, a holding surface 613, a surface 635 on a side opposite to the holding surface, a through hole 619, and a through hole 625. In FIG. 6, only one circle corresponding to each of the supporting projection 611 and the through hole 625 is denoted by a reference sign, but a plurality of these are provided in the holding plate 607. A circle having the same shape as the circle indicated by each reference sign similarly indicates the supporting projection 611 or the through hole 625. The holding plate 607 is made of, for example, alumina. The actuator 615 includes a link mechanism 617 and a shaft 627. The gravity canceling portion 246 supports a push mechanism 621 and includes a temporary holding controlling portion 639. The push mechanism 621 has the push-up pin 623.

As illustrated in FIGS. 6 and 9, the fine moving stage 230 includes a plurality of the supporting portions 601 vertically immediately below an end portion of the base plate 603. The supporting portions 601 support the base plate 603. The base plate 603 supports a plurality of the actuators 615. The base plate 603 is made of, for example, aluminum. The holding portion 220 includes the plate springs 605 on four sides thereof. Each plate spring 605 is screwed to the base plate 603 and the holding plate 607, and couples the base plate 603 and the holding plate 607.

As illustrated in FIG. 6, the holding plate 607 has a plurality of (two in the example of FIG. 8) the through holes 619 inside the circle indicated by the broken line. The gravity canceling portion 246 supports the push mechanism 621 under each through hole 619. The push-up pin 623 penetrates through the fine moving stage 230 and the base plate 603 such as not to come into contact with them. This prevents heat and vibration of the push-up pin 623 from being transmitted to the fine moving stage 230. The temporary holding controlling portion 639 controls each push mechanism 621, and the push mechanism 621 takes the push-up pin 623 in and out of the through hole 619 in the vertical direction. The push mechanism 621 is, for example, a ball screw.

In a state where the holding surface 613 does not hold the substrate 121, the push mechanism 621 pushes out the push-up pin 623 such that an upper end of the push-up pin 623 is higher than the holding surface 613. When the second transfer robot 134 places the substrate 121 on the push-up pin 623, the push-up pin 623 temporarily holds the substrate 121. When the push mechanism 621 retracts the push-up pin 623 that temporarily holds the substrate 121 further vertically downward than the holding surface 613, the holding surface 613 supports the substrate 121 instead of the push-up pin 623. The push-up pin 623 is also used in a case where the substrate 121 held on the holding surface 613 is retracted by a step substantially reverse to the above step.

The holding plate 607 includes the suction portion 609 and the plurality of supporting projections 611 inside the circle indicated by the broken line. A virtual surface defined by tip ends of the plurality of supporting projections 611 forms the holding surface 613. The supporting projections 611 support the substrate 121. The suction portion 609 is coupled to the negative pressure source 633 through the valve 629. The holding controlling portion 631 controls opening and closing of the valve 629, and when the holding controlling portion 631 releases the valve 629, the suction portion 609 and the negative pressure source 633 communicate with each other. When the supporting projections 611 support the substrate 121 and the holding controlling portion 631 releases the valve 629, the pressure between the holding plate 607 and the substrate 121 is reduced, and the holding plate 607 adsorbs and holds the substrate 121. In other words, the holding plate 607 and the holding controlling portion 631 constitute a vacuum chuck that holds the substrate 121.

The holding plate 607 further has the through hole 625 inside the circle indicated by the broken line in FIG. 6. As illustrated in FIG. 9, the holding portion 220 includes the actuator 615 below each through hole 625. The through hole 625 and the actuator 615 are disposed concentrically with respect to the holding plate 607.

The through hole 619 is not disposed at a center of the holding plate 607. The substrates 121 are bonded to each other by the bonding wave, and the through hole 619 is not disposed at the center of the holding plate 607, that is, at an ideal starting point of the bonding wave, whereby a bonding deviation between the substrates 121 is prevented.

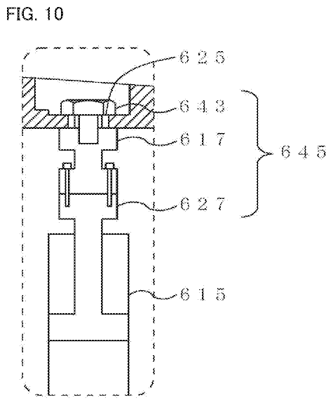

FIG. 10 is a schematic enlarged view of a portion indicated by a broken line in FIG. 9. The actuator 615 is coupled to the shaft 627, and the shaft 627 extends in a vertically upward direction. An end portion of the shaft 627 that is not coupled to the actuator 615 is screwed to the link mechanism 617. An end portion of the link mechanism 617 that is not screwed to the shaft 627 is in contact with a lower surface of the holding plate 607. The actuator 615 displaces the holding plate 607 in the vertically upward direction through the shaft 627 and the link mechanism 617.

The through hole 625 has a counterbore, and a bolt 643 is disposed in the counterbore. The bolt 643 disposed in the counterbore is embedded in the link mechanism 617, and the bolt 643 screws the holding plate 607 and the link mechanism 617. The actuator 615 is coupled to the holding plate 607 through the shaft 627 and the link mechanism 617. As a result, the actuator 615 displaces the holding plate 607 vertically downward.

In other words, it can also be said that the shaft 627, the link mechanism 617, and the bolt 643 collectively constitute a coupling member 645. At this time, the coupling member 645 is inserted into each of the plurality of through holes 625, and is coupled to the corresponding actuator 615 among the plurality of actuators 615.

The deformation controlling portion 637 individually controls each actuator 615. When the deformation controlling portion 637 controls the actuator 615 and the shaft 627 is displaced in a normal direction (that is, a vertically up-down direction in FIGS. 7 to 10) of the holding surface 613, the actuator 615 deforms the holding plate 607 in the normal direction of the holding surface 613. The holding surface 613 has a predetermined uneven shape in a state where the actuator 615 is not operated. In the example illustrated in FIG. 9, the predetermined uneven shape is a shape in which the periphery is more convex than the center.

The surface 635 of the holding plate 607 on the side opposite to the holding surface 613 is flat in a state where the actuator 615 is not operated. As a result, the link mechanism 617 is easily screwed to the corresponding through hole 625, and the assembly of the holding portion 220 is facilitated.

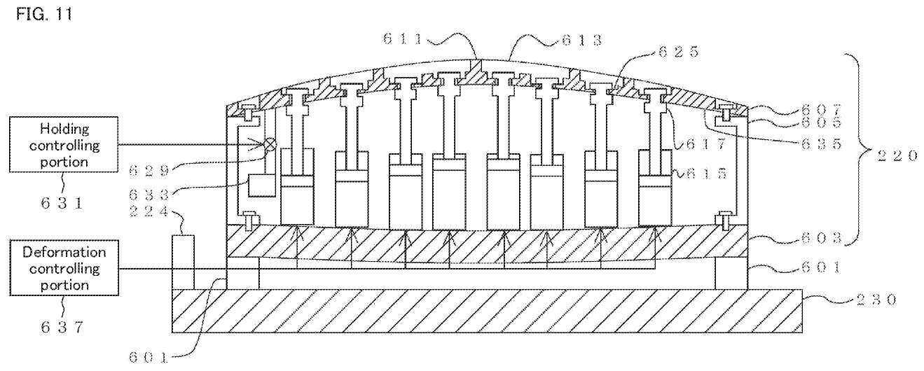

FIG. 11 illustrates the holding portion 220 in a state where the actuator 615 is operated in a C-C section. Elements common to those in FIGS. 7 to 10 are denoted by the same reference numerals, and redundant description is omitted. FIG. 11 illustrates an example in which the holding surface 613 is deformed to have a curvature larger than that in FIG. 9. In this case, the actuator 615 deforms the holding plate 607 to be more convex in the vertically upward direction.

When the actuator 615 operates and applies a force for deforming the holding plate 607, a reaction force thereof acts on the base plate 603. For example, in the example illustrated in FIG. 11, since the actuator 615 pushes up the center of the holding plate 607, a reaction force for pushing down the center acts on the base plate 603.

When the base plate 603 is deformed by this reaction force, the deformation may further deform the fine moving stage 230 through the supporting portion 601. For example, in the example illustrated in FIG. 11, the center of the base plate 603 is recessed by the reaction force, that is, the periphery is deformed such as to be relatively raised. Here, for example, when the supporting portion 601 has a solid block shape with high rigidity, a force for deforming such that deformation of the base plate 603 causes the periphery of the fine moving stage 230 to be relatively raised through the supporting portion 601 acts. In such a case, a force in the vertically upward direction and a force in the horizontal direction pulled toward the center of the base plate 603 act on the supporting portion 601.

When the fine moving stage 230 is deformed, the reflecting mirror 224 provided on the fine moving stage 230 is inclined. When the reflecting mirror 224 is inclined, the position where the light of the interferometer 222 hits the reflecting mirror 224 is different from that when the reflecting mirror 224 stands upright, and thus, there is a possibility that the interferometer 222 erroneously detects the position of the fine moving stage 230. Also, due to the deformation of the fine moving stage 230, the reflecting mirror 224 is displaced in a moving direction of the fine moving stage 230, for example, in the horizontal direction, which may cause erroneous detection.

Therefore, in the present preferred embodiment, a mechanism that is deformed according to the reaction force of the actuator 615 generated in the base plate 603 is provided between the fine moving stage 230 and the base plate 603. The deformation of this mechanism can prevent deformation of the fine moving stage 230.

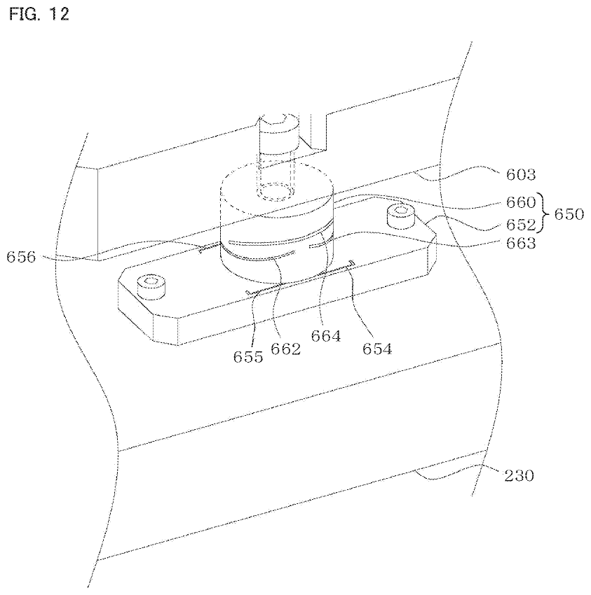

FIG. 12 schematically illustrates a hinge 650 used as the supporting portion 601. The hinges 650 are disposed between the base plate 603 and the fine moving stage 230 at four locations indicated as the supporting portions 601 by alternate long and short dashed lines in FIG. 6. In the example illustrated in FIG. 6, the hinge 650 is provided corresponding to a position where the plate spring 605 is provided, but may be provided at another position.

The hinge 650 includes a plate-shaped hinge portion 652 and a cylindrical tilt hinge portion 660 disposed on the hinge portion 652. The hinge portion 652 is screwed to the fine moving stage 230. The tilt hinge portion 660 is screwed to the base plate 603.

The hinge portion 652 has four grooves around the tilt hinge portion 660 in an upper surface of the hinge portion 652. In FIG. 12, only grooves 654, 655, and 656 are illustrated, but there is another groove hidden by the tilt hinge portion 660. Specifically, there is another groove facing the groove 654 just like how the groove 655 and the groove 656 face each other with the tilt hinge portion 660 interposed therebetween. The four grooves including the grooves 654, 655, and 656 extend in a direction orthogonal to a radial direction of the substrate 121 or the holding plate 607. Each of the four grooves including the grooves 654, 655, and 656 has a shape of “[” (square bracket). The tilt hinge portion 660 can move in the horizontal direction, particularly in the radial direction of the substrate 121 or the holding plate 607, by the four grooves including the grooves 654, 655, and 656. Therefore, the hinge 650 is deformed according to the radial movement of the base plate 603 with respect to the fine moving stage 230. As a result, even when the base plate 603 is deformed in the radial direction by the reaction force of the actuator 615, the hinge 650 is also deformed according to the deformation, and the fine moving stage 230 is prevented from being deformed. The number and shape of the grooves of the hinge portion 652 are an example. The present invention is not limited thereto.

The tilt hinge portion 660 has four grooves in a side surface. In FIG. 12, only grooves 662, 663, and 664 are illustrated, but there is another groove on the back side of the tilt hinge portion 660. By the grooves 662 and 663, the tilt hinge portion 660 can be deformed in a rotation direction around the radial direction of the substrate 121. In addition, by the groove 664 and another groove (not illustrated), the tilt hinge portion 660 can be deformed in the rotation direction around a direction orthogonal to the radial direction of the substrate 121. As a result, even when the base plate 603 is inclined with respect to the planar direction of the substrate 121 by the reaction force of the actuator 615, the tilt hinge portion 660 is also deformed according to the inclination, and the fine moving stage 230 is prevented from being deformed. The number of grooves of the tilt hinge portion 660 is an example, and is not limited to four.

As described above, the hinge 650 functions as a mechanism that is deformed according to the reaction force of the actuator 615 generated in the base plate 603. In other words, it can be said that the hinge 650 prevents deformation of the fine moving stage 230 against deformation of the base plate 603. This can also be said that the reaction force of the actuator 615 is prevented from being transmitted to the fine moving stage 230.

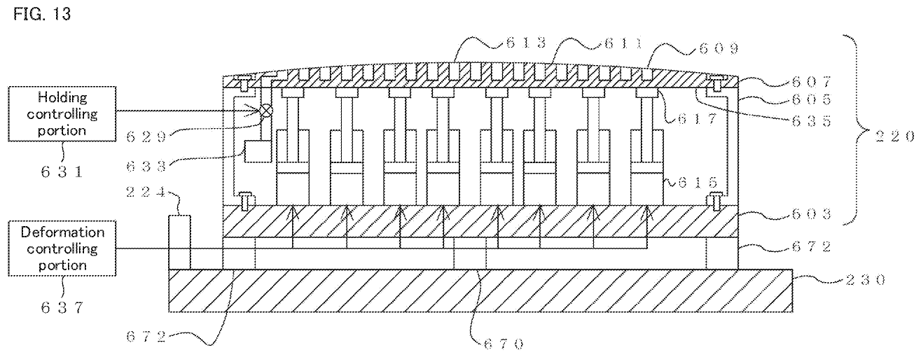

FIG. 13 illustrates an arrangement for preventing deformation of the fine moving stage 230 instead of the hinge 650 which is the supporting portion 601 of FIG. 12. FIG. 13 schematically illustrates a fixing supporting portion 670 and a damper 672 which are used as supporting portions. The fixing supporting portion 670 is disposed at a position corresponding to the center of the holding plate 607. In other words, it can be said that the fixing supporting portion 670 is disposed in a region overlapping the center of the base plate 603. The fixing supporting portion 670 is, for example, a solid block-shaped member having high rigidity, and is screwed to each of the base plate 603 and the fine moving stage 230 to fix and support them.

The dampers 672 are disposed between the base plate 603 and the fine moving stage 230 at four locations indicated as the supporting portions 601 in FIG. 6, and connect them. In the example illustrated in FIG. 6, the damper 672 is provided corresponding to the position where the plate spring 605 is provided. In other words, it can be said that a plurality of the dampers 672 are disposed in a region overlapping an edge of the base plate 603. The dampers 672 may be provided at other positions, and the number of dampers 672 is not limited to four.

In FIG. 13, the base plate 603 is fixed and supported at one location by the fixing supporting portion 670. Therefore, even if the base plate 603 is deformed, the deformation is hardly transmitted to the fine moving stage 230.

The damper 672 also supports the base plate 603 with respect to the fine moving stage 230. Here, the damper 672 absorbs deformation of the base plate 603. Accordingly, the damper 672 functions as a mechanism that is deformed according to the reaction force of the actuator 615 generated in the base plate 603. In other words, it can be said that the damper 672 and the fixing supporting portion 670 prevent deformation of the fine moving stage 230 against deformation of the base plate 603. This can also be said that the reaction force of the actuator 615 is prevented from being transmitted to the fine moving stage 230.

The base plate 603 may be made of a metal material other than aluminum. The base plate 603 may be made of a ceramic material. The base plate 603 may be made of alumina, SiC (silicon carbide), or low thermal expansion ceramic. The holding plate 607 may be made of a ceramic material other than alumina. The holding plate 607 may be made of SiC (silicon carbide) or low thermal expansion ceramic.

In addition to the arrangement of FIG. 12 or 13, the deformation of the fine moving stage 230 may be prevented by increasing the rigidity of at least one of the base plate 603 and the fine moving stage 230. Examples of a method for increasing the rigidity include increasing the thickness, using a material having high rigidity, etc.

Furthermore, in addition to the arrangement of FIG. 12 or 13, the detection result of the interferometer 222 may be corrected on the basis of the deformation amount of the fine moving stage 230 due to the reaction force of the actuator 615. In this case, how much the reflecting mirror 224 is deformed by the driving of the actuator 615 may be grasped by analysis and actual machine measurement, and the position of the fine moving stage 230 may be corrected according to the driving amount of the actuator 615.

Although the preferred embodiments have been described above, the technical scope of the present invention is not limited to the scope described in the above preferred embodiments. It is apparent to those skilled in the art that various modifications or improvements can be made to the above preferred embodiments. It is apparent from the description of the claims that modes to which such modifications or improvements are made can also be included in the technical scope of the present invention.

It should be noted that the execution order of each processing such as operations, procedures, steps, and stages in the apparatuses, systems, programs, and methods illustrated in the claims, the specification, and the drawings can be realized in an arbitrary order unless “before,” “prior to,” etc., is particularly clearly indicated and the output of the previous processing is used in the subsequent processing. Even if the operation flow in the claims, the specification, and the drawings is described using “First,” “Next,” etc., for convenience, it does not mean that it is essential to perform in this order.

What is claimed is:

1. A substrate holding apparatus comprising:
a holding plate that holds a substrate on a holding surface;
a plurality of actuators that are coupled to the holding plate and deform the holding plate at least in a normal direction of the holding surface;
a base plate that supports the plurality of actuators;
a table main body that supports the base plate; and
a mechanism that is disposed between the table main body and the base plate and is deformed according to a reaction force of the plurality of actuators generated in the base plate.

2. The substrate holding apparatus according to claim 1, wherein the mechanism has
a fixing supporting portion that fixes and supports the base plate and the table main body, and
a damper disposed between the base plate and the table main body.

3. The substrate holding apparatus according to claim 2,
wherein the fixing supporting portion is disposed in a region overlapping a center of the base plate, and
a plurality of the dampers are disposed in a region overlapping an edge of the base plate.

4. The substrate holding apparatus according to claim 1, wherein the mechanism has a hinge that prevents deformation of the table main body against deformation of the base plate.

5. The substrate holding apparatus according to claim 4, wherein the hinge is deformed according to at least one of inclination and radial movement of the base plate.

6. The substrate holding apparatus according to claim 1, further comprising a plate spring that couples the base plate and the holding plate.

7. The substrate holding apparatus according to claim 1, wherein each of the plurality of actuators has a link mechanism that is movable in a planar direction with respect to the holding plate and transmits displacement of the actuator in the normal direction.

8. The substrate holding apparatus according to claim 1, further comprising an index that is disposed on the table main body and detects a position of the table main body.

9. A substrate bonding apparatus comprising:
a substrate holding apparatus according to claim 1; and
a substrate holding portion that holds another substrate,
wherein the substrate and the other substrate are bonded to each other by at least one of the substrate holding apparatus and the substrate holding portion moving such as to approach the other.

10. The substrate bonding apparatus according to claim 9, wherein the substrate holding apparatus is movable in the planar direction of the substrate.
